(19) United States
(12) Patent Application Publication
(10) Pub. No.: US 2006/0204859 A1
(43) Pub. Date: Sep. 14, 2006

(54) AN EXTRA DOSE TRIM MASK, METHOD OF MANUFACTURE, AND LITHOGRAPHIC PROCESS USING THE SAME

(75) Inventors: Robert K. Leidy, Burlington, VT (US); Charles J. Parrish, Milton, VT (US); Jed H. Rankin, South Burlington, VT (US); David Shanks, Williston, VT (US); Charles A. Whiting, Milton, VT (US)

Correspondence Address: SCULLY, SCOTT, MURPHY & PRESSNER, 400 GARDEN CITY PLAZA, GARDEN CITY, NY, 11530, US

(73) Assignee: INTERNATIONAL BUSINESS MACHINES CORPORATION, Armonk, NY (US)

(21) Appl. No.: 10/906,846

(22) Filed: Mar. 9, 2005

(51) Int. Cl. G03C 5/00; G03F 1/00

(52) U.S. Cl. 430/5; 430/394; 430/322; 430/323; 430/324

(57) ABSTRACT

A mask structure and photolithographic method using the same for obtaining shorter and thinner line or feature lengths for optimizing power consumption and performance in semiconductor devices. According to a first aspect, a method for enabling trimming of semiconductor linewidth dimensions implements an extra dose trim mask. The lithographic method using the extra dose trim mask to make small adjustments to patterned linewidth exposures for enhanced CD control may be used to trim or adjust whole or a plurality of regions of a lithographic exposure. There is additionally provided a structure and method of creating a lithographic dual exposure mask having one or more regions comprising one or more partial energy absorptive layers such that, when subject to a blanket dose, enable smaller image size adjustments in those regions. The method using a dual exposure trim mask having multiple attenuator regions facilitates product/process tuning as multiple trim doses may be delivered to different regions of an exposure field resulting in different image size adjustments.

### BACKGROUND OF THE INVENTION

1. Field of the Invention

The present invention related generally to the fabrication of semiconductor circuit chips, and more particularly, to a novel lithographic process and attenuating mask for use thereof for achieving shorter feature dimensions, e.g., gate channel lengths, in semiconductor circuit devices; and further, to processes for making and using the attenuating mask during the semiconductor chip fabrication process to optimize chip circuit power consumption and circuit performance.

2. Description of the Prior Art

As technology requirements become more and more stringent, Critical Dimension (CD) control, especially for FET transistor gate level, becomes more critical. Additionally, using current lithographic methods, and the extensive Optical Proximity Correction (OPC) requirements, the model building, and masks are very difficult and expensive to build. Additionally, there is inherent variability in the mask manufacture process, lithography stepper lenses, proximity dependant processes (density of etch load, develop, etc, at mask and wafer), and OPC errors. These variables can result in some regions, or some circuits in the chip being a different dimension relative to other regions or circuits.

At the device gate level, lithography to achieve high performance shorter channel lengths are now required. However, this leads to increased leakage due to the short channel effect on so many transistors in today's chips. To circumvent this, technologies are now being developed with multiple device targets for linewidth. Historically, poly (gate) linewidth had been designed on grids (data defined) with inability to achieve perfect linearity among the grid elements. The mask is written on a grid with the data defined by the grid coordinates (vertices). However, the mask write time increases as the grid increment decreases which is not cost effective for trimming linewidth dimensions. Thus, to optimize the power/performance criteria in new chip designs using grid increments (data defined) necessitates the development of several masks to evaluate different linewidth increments which is an expensive proposition. Thus, to independently control these targets with data preparation can be difficult because of the coarse increments that are currently achievable.

Recently, a hardmask with Chemical Oxide Removal (COR) trim has been used to get independent control of the nominal and the trimmed shorter device. However, the hardmask trim with a COR process wherein a vapor or a plasma of HF and NH₃ is employed as the etchant and low pressures (of about 6 millitorr or below) are used, attacks an outside corner so an additional layer of dielectric, e.g., a nitride, was added to protect the corner. It was found that all of this additional processing is expensive and defect prone.

It would thus be desirable to provide a lithographic dual exposure mask structure along with a method of manufacturing this mask to enable smaller image size adjustments than would be permitted by the prior art.

It would further be highly desirable to provide a lithographic method using a secondary, “dual-exposure” mask to “trim” or make small adjustments to exposures of a region or plurality of regions of a lithographic exposure.

It is the case moreover, that semiconductor device models and timing models and tools have errors which may result in timing or performance differentials between various parts of a chip that can either impede or benefit functionality and yield. Thus, it would be further highly desirable to additionally provide a novel mask structure and method to “tune” the CD of specific parts of a semiconductor chip to ameliorate any of the errors, timing or performance differentials or, otherwise enhance performance or optimize power consumption of the chips.

### SUMMARY OF THE INVENTION

This invention is directed to a novel mask structure and photolithographic method using the same for obtaining shorter and thinner line or feature lengths for increasing or optimizing power consumption and performance in semiconductor devices.

According to a first aspect of the invention, there is provided a method for enabling trimming of semiconductor linewidth dimensions implementing a novel dose trim process. According to this aspect of the invention, a lithographic mask is shrunk before performing an etch process by adding a second mask layer and providing an extra exposure dose. That is, a softmask (photoresist) is implemented to enable a second energy exposure of a region having a patterned resist in order to reduce the size (shrink) the resist to a tailored dimension. Thus, according to this aspect of the invention, the same block mask can be used with an extra exposure step performed locally. The added exposure dose give a combined effect of trimming the desired line or feature. In accordance with this aspect of the invention, there is employed the capability of the state of the art lithography tools to process two masks on a wafer. The first mask is a standard gate level mask printing all of the standard features. The second mask is the dual exposure trim mask but run sequentially after (or before) the gate level mask giving an extra dose into these regions. Advantageously, this extra sub-threshold dose trims down the lines in the area exposed without degrading the resist profiles. This achieves the same result after etching with a softmask that was achieved with the COR process trim, but it does it with thirteen (13) fewer steps and lower defect levels.

Advantageously, the lithographic method using a secondary, “dual-exposure” mask to “trim”, or make small adjustments to patterned linewidth exposures for enhanced CD control may be used to trim or adjust whole regions or a plurality of regions of a lithographic exposure.

Thus, according to a second aspect of the invention, there is provided use of a photomask having a plurality of regions with no optical blocking absorber, surrounded by a fully absorptive light blocking material. However, in order to effect smaller image size adjustments on the order of less than about 5 nm, an incremental exposure dose of much less than 1 mJ/cm² would be necessary, which is typically smaller than the capability of most alignment equipment. Thus, according to a further aspect of the invention, there is provided a structure and method of creating a lithographic dual exposure mask having one or more regions comprising one or more partial energy absorptive layers such that, when subject to a blanket dose, enable smaller image size adjustments in those regions than would be permitted by the prior art. This is done by filling the regions of the dual exposure mask with an attenuator material with substantially non-unity transmission, permitting the dosing on the aligner to be increased to an achievable value. This method using a dual exposure trim mask with a multiplicity of attenuators facilitates product/process tuning as multiple trim doses may be delivered to different regions of an exposure field resulting in different image size adjustments within one lithographic field.

Advantageously, the novel attenuating mask structure and method of use can be used with the dose limitations on current state of the art the lithography tools to address the desired small CD changes on wafer.

### BRIEF DESCRIPTION OF THE DRAWINGS

The objects, features and advantages of the present invention will become apparent to one skilled in the art, in view of the following detailed description taken in combination with the attached drawings, in which:

FIG. 1 depicts the dual-exposure “trim” mask process according to the present invention;

FIGS. 2(a)-2(f) depict the process flow for creating a novel mask which has attenuating material in the lithographically active area of a chip;

FIG. 3 describes a dual exposure (trim) mask structure 110 and method of creating a dual exposure mask with one or more regions R1, R2, R3 comprising one or more partially absorptive layers;

FIGS. 4(a)-4(c) depict, through cross-section views, various dual trim exposure photomask structures comprising a material layer substantially transparent at the exposure wavelength and a blanket film that is (are) effectively opaque at the exposure wavelength, and a plurality of regions R1, R2 and R3 which are partially transmissive at the exposure wavelength; and,

FIG. 5 conceptually depicts a lithographic field with m×n chip matrixing; whereby individual dose adjustments by chip is possible, not just by field.

### DETAILED DESCRIPTION OF THE PREFERRED EMBODIMENTS

According to the first aspect of the invention, there is provided a method for enabling trimming of semiconductor linewidth dimensions implementing a novel dose trim process. According to this aspect of the invention, a lithographic mask is shrunk before performing the polysilicon (gate linewidth) etch process by adding a second mask layer and providing an extra exposure dose. That is, a softmask comprising a patterned resist is subject to a second blanket light exposure dose in a region in order to reduce the size (shrink) the resist to achieve a tailored linewidth dimension. Thus, according to this aspect of the invention, the same block mask can be used with an extra exposure step performed locally. The added exposure dose provides a combined effect of trimming the linewidth dimension at the exposed regions. Basically, the system for performing the extra dose trim employs the capability of the state of the art lithography tools to process two masks on a wafer.

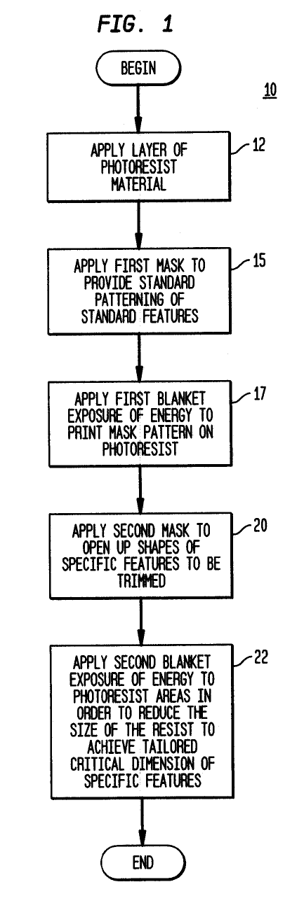

Particularly, as shown in the extra trim dose process flow 10 of FIG. 1, after a layer of photoresist material is applied according to standard gate level processing at step 12, a first mask is implemented at step 15 to provide the gate level patterning image used for printing all of the standard features. Then, at step 17, for example, the wafer is aligned, stepped and the reticle is scanned to expose the wafer to energy doses (e.g., milliJoules of energy) for printing the mask image into the photoresist. At step 20, second mask is then provided, e.g., a different reticle, having a block pattern to open up shapes to be trimmed down that is then exposed with another dose (e.g., a blanket exposure in a region of the particular chip) at step 22. The second mask is a block mask which may be the same block mask that may be used to define the (chemical oxide removal) COR trim, but run sequentially after (or before) the gate level mask giving an extra dose into these regions. This extra sub-threshold dose trims down the lines in the area exposed without degrading the resist profiles. This achieves the same result after etching with a softmask that was achieved with the COR trim, but it does it in fewer steps and with decreased amount of defect levels. The second mask may alternatively comprise a mask structure described hereinbelow having pre-defined areas or shapes of partially transmissive regions providing various layers of energy attenuation that will enable tuning of the performance of certain chip device in the pre-defined areas of the chip. Thus, the dual exposure trim mask of the invention may be implemented in a base lithographic process to “tune” the CD of specific parts of a chip. That is, the addition of an additional dose in a “blanket” technique can reduce the dimensions of these features, without severely impacting the process window, and by only using the low cost, block mask. With the resist speed of the current 193 nm photoresist materials, when applying a blanket dose, an effective dose of approximately 1 mJ results in approximately 20 nm of CD “thinning”. The desired “tuning” to mitigate the undesirable effects described above is intended to change the CD by approximately 2-5 nm. Current lithography tools have a minimum deliverable dose of approximately 1 mJ. Thus, according to a further aspect of the invention, a novel method and a structure for creating masks which can be used with the dose limitations on the lithography tools to address the desired small CD changes on wafer is now described.

According to this aspect of the invention, there is provided a process for creating a mask which has attenuating material in the lithographically active area of the chip, but exposes reticle alignment and tool recognition marks. This aspect of the invention provides a method and a structure for creating masks which can be used with the dose limitations on the lithography tools to address the desired small CD changes on wafer.

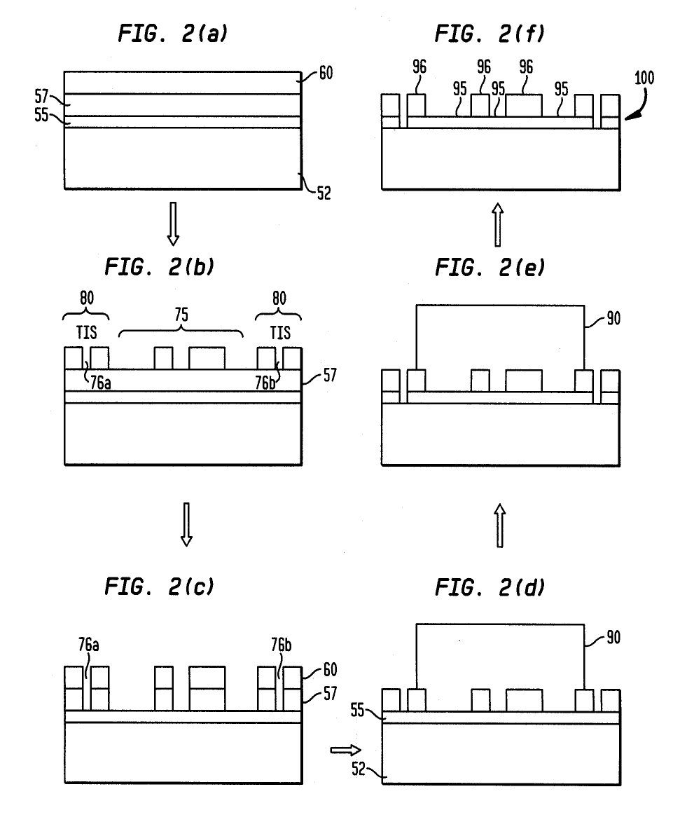

FIGS. 2(a)-2(f) particularly depict the process flow for creating a mask which has attenuating material in the lithographically active area of the chip, but exposes reticle alignment and tool recognition marks, for example. As shown in FIG. 2(a), an attenuated phase shift mask (SPSM) 50 is provided having a 193 SPSM quartz substrate 52 and chrome attenuator 57. In between the lower quartz substrate and the chrome attenuator layer is an attenuator (partially transmissive) layer 55 comprising materials such as MoSi, or like attenuator material layer. After forming a photoresist layer 60 on top of the chrome attenuator layer 57, in a next step, a patterned mask is applied and the resist is patterned, developed and etched to form holes in the outer attenuator frame region 80 outside the chip region 75 that function to enable the reticle to align in the lithographic tool. That is, as shown in FIG. 2(b), the chrome attenuated mask is provided with Transmissive Image Sensor (TIS) holes 76a, 76b in the frame region 80 that enable reticle alignment. These TIS holes 76a,b enabling alignment of the mask will be subsequently etched to form alignment marks that align the reticle to the tool. Preferably, the photoresist 60 is exposed to develop the resist according to the desired chip 75 and frame regions 80, and then, a wet etch of the chrome layer 57 utilizing known etchants is performed as shown in FIG. 2(c). The patterned phototresist layer 60 is subsequently stripped as shown in FIG. 2(d). Proceeding as indicated in FIG. 2(d), a further photoresist layer 90 is applied to the chip region 75 on top of the chrome pattern to block the chip pattern while exposing the frame alignment (TIS) holes 76a,b. Then, as shown in FIG. 2(e), an etch process is performed, e.g., utilizing conventional lithography and (reactive-ion etching (RIE), plasma-etching, ion beam etching and other like dry etching processes), to remove the MoSi material attenuator 55 at the TIS holes 76a,b to form the alignment features. Finally, as shown in FIG. 2(f), the further photoresist layer 90 is removed (stripped) to form the final mask. The resulting attenuated phase shift mask 100 resulting from the process depicted in FIGS. 2(a)-2(f) includes reticle alignment features 76a,b and within the chip region 75, attenuator regions 95 such as patterned MoSi or like partially transmissive material enabling partial light transmissivity, e.g., 93%, and light blocking regions 96, e.g., of chrome. Thus, when implementing the mask 100 of the present invention, only about 7% of the applied energy will be transmitted in the attenuated regions 95 and no light will pass through the chrome regions 96.

Advantageously, the lithographic system and method using a secondary, “dual-exposure” mask 100 to “trim”, or make small adjustments to patterned linewidth exposures for enhanced CD control may be used to trim or adjust whole regions or multiple regions of a lithographic exposure. That is, the dual-exposure “trim” mask process may be used to selectively tune a region or regions of patterned linewidths to an image size different than the remainder of a lithographic field. In one embodiment, a photomask for a dual “trim” process may be implemented with a plurality of clear regions with essentially 100% transmission (i.e., with no optical blocking absorber), surrounded by a fully absorptive light blocking material. However, it has been shown that incremental small blanket exposures in each region, on the order of 1 mj/cm², result in extremely significant image size changes, on the order of 10 or more nm, which may be too large for many applications. Incremental doses at the wafer plan on the order of 0.1 mJ would be desirable for some applications, yet this is lower than the minimum dose delivery threshhold for some lithography alignment equipment. Thus, due to the use of a clear region(s) for the trim exposure, only a single trim dose (and thus, change in image size) is possible.

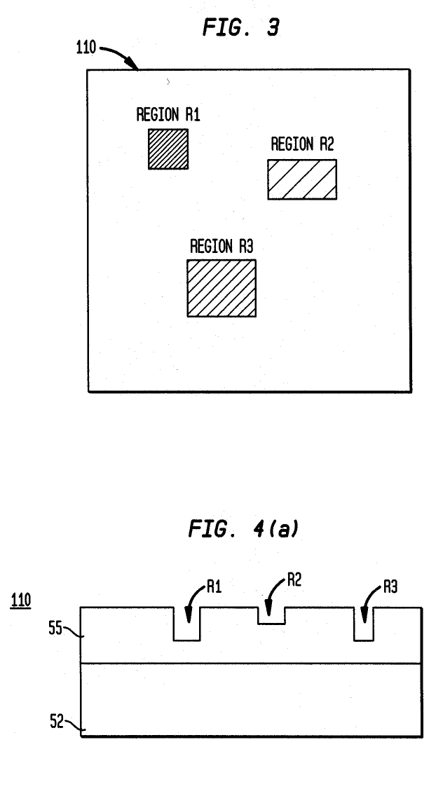

In an alternative embodiment, according to a further aspect of the invention, there is additionally provided a trim mask 110 comprising one or more trim regions R1, R2, R3 covered by an attenuator or layer of attenuators, and a manner of manufacturing the trim mask. The solution provided by dual exposure trim mask 110 of FIG. 3 permits smaller trim dosing at the wafer plane, thus resulting in smaller image size changes than would be permitted by the prior art. It also permits multiple trim doses to be delivered to different regions of an exposure field using one mask, resulting in different image size adjustments within one lithographic field.

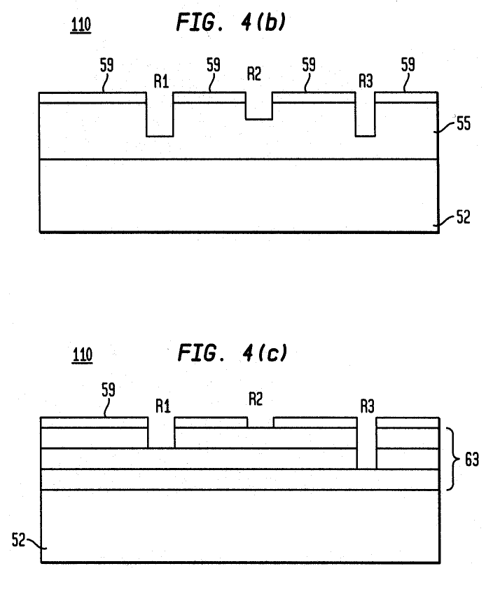

Particularly, FIG. 3 describes a dual exposure (trim) mask structure and method of creating a dual exposure mask with one or more regions comprising one or more partially absorptive layers. That is, each of select regions R1, R2, R3 of the dual exposure mask is filled with an attenuator having substantially non-unity transmission, permitting the dosing on the aligner to be increased to an achievable value. FIGS. 2(a)-2(f) particularly depict the process flow for manufacturing such a dual exposure (trim) mask which has attenuating material in the lithographically active area 75 of the chip that enables smaller image size adjustments than would be permitted by the prior art. For instance, in FIG. 2(e), the resist mask 90 may be patterned to open up a hole (not shown) utilizing conventional lithography to enable etching of the attenuator layer, e.g., MoSi layer 55, that would provide 100% light transmission (e.g., providing on the order of about 20 nm of trimming with a single applied dose) and leave the remaining attenuator regions providing 7% light transmission (e.g., providing on the order of about 3 nm of trimming with the same single applied dose). As shown herein with respect to FIG. 4(a), part of the attenuator layer 55 may be etched or partially etched to a desired thickness to tailor the amount of light transmissivity in specific regions R1, R2, R3. That is, the light attenuator layer 55 of the mask 110 may be etched to specific depths to tailor the light transmissivity in multiple areas of the chip may be tuned to different dimensions. This may be done by a controlled etch in the process step of FIG. 2(e), or, as will be described in greater detail, by placing different attenuating layers and etching through in a more controlled way. The film thus will have substantially non-unity transmission, permitting a larger incident energy to be delivered to the mask plane to achieve the desired secondary exposure dose. This in turn will permit smaller trim adjustments in the secondary exposure areas which would not have been possible due to minimum dose delivery constraints on the aligner.

The photomask structure 110 described with respect to FIG. 4(a) comprises a material layer 52 substantially transparent at the exposure wavelength (e.g., quartz for current optical lithography), a blanket film 55 (or series of films) that is(are) effectively opaque at the exposure wavelength, and a plurality of regions R1, R2 and R3 which are partially transmissive at the exposure wavelength. The opaque regions of the photomask 110 may comprise a single attenuator film of a thickness sufficient to appreciably absorb all light at the exposure wavelength. As shown in FIG. 4(b), the opaque regions of the photomask 110 may alternately comprise a single attenuator film 55 of arbitrary thickness covered by a blocker film 59 which is substantially opaque at the exposure wavelength. As shown in FIG. 4(c), the opaque regions of the photomask 110 may alternately comprise a multi-film stack 63 of different attenuator layers whose aggregate attenuation appreciably absorbs all light at the exposure wavelength. It is understood that attenuator stack layers may comprise other attenuating material known in the art. The opaque regions of the photomask 110 may alternately comprise a multi-film stack 63 of different attenuators of arbitrary attentuation, covered by a blocker film 59 that is substantially opaque at the exposure wavelength.

The partially transmissive regions R1, R2 and R3 of the photomask 110 may comprise: one or more discrete thicknesses of a single attenuator film. Since absorption in these films will typically be of the form I/I₀=exp(−x/L), where “I₀” is the incident light intensity, I is light intensity exiting the attenuator, x is the attenuator thickness, and L is a characteristic absorption length specific to the material and light wavelength, each region R[i] with attenuator thickness x[i] will have transmission property I[i]/I₀=exp(−x[i]/L), where subscript [i] represents the properties specific to each region R[i]. The partially transmissive regions R1, R2 and R3 of the photomask 110 may alternately comprise: one or more discrete thicknesses of different attenuator films of thickness x[1], x[2], x[3], . . . etc. with characteristic absorption lengths L[1], L[2], L[3] . . . . Each region R[i] may have one or more of the attenuator films contained, stacked from base substrate. For example, a given region might contain only attenuator 1, or attenuators (1,2,3), but do not have attenuator combination (1,3). Thus, attenuation for each region would be a product of the transmission percentage of the aggregate stack: I[i]/I₀=Product of (exp(−x[j]/L[j])), j=1 to n, where n is the number of attenuators in the film stack.

There are a variety of methods to construct the mask shown in FIGS. 4(a)-4(c). In a “subtractive” method, first all films needed on photomask are deposited using known methods, including but not limited to, evaporation, sputtering, CVD, PECVD, LPCVD. For the embodiment of a photomask 110 having a single attenuator film of a thickness sufficient to appreciably absorb all light at the exposure wavelength, first the entire mask is coated with a photoresist. Then, a region R[i] is exposed and developed out. For those film stacks comprising a blocker layer that is substantially opaque at the exposure wavelength, an etch (e.g., a wet etch or reactive ion etch) is performed to remove the blocker from the clear opening. Then, each attenuator is etched for a specific period of time t[i], e.g., attenuator region R[1] is etched for a time t[1], which will leave desired attenuator thickness x[i] in Region i. Then, the resist is stripped and the process repeated for as many times as is necessary to define number of regions R[I]. In a subtractive method, for the embodiment of a photomask 110 having a multi-film stack of different attenuators whose aggregate attenuation appreciably absorbs all light at the exposure wavelength, all regions R[i] which require the top attenuator film to be removed are first exposed and developed out. After developing, the top attenuator is etched and the resist stripped. Then, those regions requiring the 2nd attenuator film to be removed are exposed and developed out. After developing, the next attenuator layer is etched and the resist stripped. This process is repeated until the desired attenuator profiles are achieved.

An “additive” method for constructing the mask shown in FIGS. 4(a)-4(c) implements film deposition techniques deposited using known methods, including but not limited to, evaporation, sputtering, CVD, PECVD, LPCVD. For the embodiment of a photomask 110 having a single attenuator film, first the thinnest layer of film needed for any given region R[i] is deposited. Then, using well known lithographic techniques, a protective film is applied over this region R[i] to prevent subsequent films from affecting it. Protective film should be sufficiently resistant that it will not be removed or damaged during subsequent processing. Then, an incremental layer of film equivalent to the difference in thickness between the thinnest film and second thinnest film in a second region is deposited. Then, this second region is masked using a same protective film according to the well known lithographic techniques. This process is repeated until all of the desired attenuator profiles are created. Finally, the protective films utilized in creating the photomask using the additive process are then stripped. In an additive method, for the embodiment of a photomask 110 having a multi-film stack of different attenuators whose aggregate attenuation appreciably absorbs all light at the exposure wavelength, each of the process steps described in connection with the single attenuator film are performed except that, for this embodiment, attenuator layers of different composition are deposited.

As mentioned, the dual expose trim mask having trim regions including an attenuator or layer of attenuators, permits smaller trim dosing at the wafer plane, thus resulting in smaller image size changes. It additionally permits multiple trim doses to be delivered to different regions of an exposure field using one mask, resulting in different image size adjustments within one lithographic field. By way of example, it may be the case that a single dose adjustment is desired, but an image size adjustment smaller than the dose threshold is desired. For example, the image size response using an unattenuated trim mask is between about 15 nm/mJ-20 nm/mJ, and a typical minimum exposure supplied by an aligner is 1 mJ. By way of a first example, if an image size adjustment of 5 nm is desired, the required trim dose would be ˜0.3 mJ, unattainable on the aligner. Thus, in this example, a trim mask 110 described herein with respect to FIGS. 4(a)-4(c) may be used with an attenuator which would absorb between, for example, between 70% and 99% of the incident light at the mask plane. This would require respectively an aligner dose delivered to the mask plane of between 0.3 mJ/(1−0.7)=1 mJ to 0.3 mJ/(1−0.99)=30 mJ, which are well within the normal dose delivery range of the aligner.

By way of a second example, it is desired to adjust the image size in a multiplicity of regions, each region receiving a different image size adjustment. For example, it is desired to adjust the image size in a first region, R[1], by 3 nm, and the image size in a second region 2, R[2], by 6 nm relative to the basis value in the rest of the field. Assuming a 15 nm/mJ response to trim dose, the dose required at the wafer plane is 0.2 mJ in region R[1] and 0.4 mJ in region R[2]. To achieve this, an attenuator which absorbs at least (1−1 mJ/0.2 mJ)=80% of the incident light at the reticle plan in region R[1], and (1−1 mJ/0.4 mJ)=60% of the light in region R[2].

In a third example, use is made of an attenuator comprising MoSi attenuator material. This MoSi attenuator material absorbs light according to the formula I/I₀=exp(−x/L), where I₀ is the incident energy density entering the attenuator, x is the attenuator thickness, and L is a characteristic absorption length equal to approximately 220 Å for this material, e.g., at the 193 nm wavelength. A common thickness for MoSi is 700 Å; thus, a full thickness of the attenuator would absorb about (1−exp(−700/220))=96% of the incident light at the reticle plan. Region R[1] requires the lowest dose, so the full thickness of attenuator would be used in this region. Hence, the requested dose from the aligner would be calculated to be 0.2 mJ*exp(700/220)=4.8 mJ. Region R[2] in the example described, requires a 0.4 mJ dose; thus, solving for the thickness in this region will obtain: 0.4 mJ/4.8 mJ=exp(−x/220); x=−ln(0.4/4.8)*220=547 Angstroms.

One application of the present invention is to make minor speed adjustments, e.g., by increasing image size [slowing down circuits], for example, in a region of a semiconductor chip product, e.g., a microprocessor including SRAM cells, leaving some of the field at nominal image size; and, decreasing image size on [speeding up circuits], e.g., those circuits believed to limit speed on the chip. This is achievable by decreasing the base exposure to set the SRAM to reference size, then creating additional regions on the trim mask with different attenuator thicknesses as described in the second example as described hereinabove.

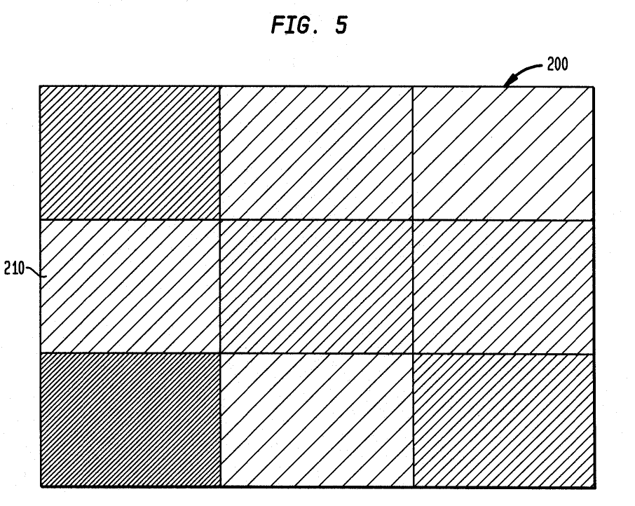

Further, it is current practice to “stripe” or deliberately deviate dosing by field, e.g., columnwise, at gate level. This creates a highly granular distribution of image size, and thus speed distribution. Advantageously, the electrical properties of these different speed chips can be used to determine proper centering for the product. However, because the various stripes are also cutting across the wafer at different radius points, there are integration factors (rapid thermal anneal (RTA) temperature, spacer deposition) convolved with the speed variation. This often limits the use of the striping data. Thus, for a field composed of m×n matrixed chips, a dual trim exposure mask with as many as m×n individual attenuator thicknesses may be created and used to create a speed distribution across each individual field. This could result in either more controlled, easily analyzed striping data; or it could provide a virtually continuous striping speed distribution rather than a small number of highly granular speed modes. FIG. 5 conceptually depicts a lithographic field with m×n chip matrixing 200; whereby individual dose adjustment by chip is possible, not just by field. Each rectangle 210 in the lithographic field with m×n chip matrixing 200 shown in FIG. 5 represents an individual chip in the lithographic field. Each chip may be given an individual dose adjustment from baseline. Thus, while it is often difficult and laborious for chip designers to identify the speed-limiting circuits in a given design (it involves lengthy, time-consuming analyses of test results to infer which circuits are critical to chip performance), a set of trim masks may be created to selectively speed up certain regions of the chip without affecting timing or speed of the remaining chip. For example, a trim mask “A” might speed up region A; mask “B”, region B, etc. By modulating only certain regions of a chip in a controlled manner, simple tests would reveal speed improvements according to region, and the limits to which these apply. For instance, if speeding up regions A and C doesn't affect overall chip speed, but speeding up region B speeds up the chip, one may infer that the speed limiting circuit is in region B. In addition, sufficient speed modulation of region B may display a point past which chip speed no longer increases, indicating that region B is no longer speed-limiting at that point. Conversely, a chip designer may know exactly which circuits are speed-limiting. In this case, a trim mask may adjust only those circuits known to affect speed distribution, while leaving the rest of the field at a slower speed, which will keep current/power consumption minimized.

While there has been shown and described what is considered to be preferred embodiments of the invention, it will, of course, be understood that various modifications and changes in form or detail could readily be made without departing from the spirit of the invention. It is therefore intended that the invention be not limited to the exact forms described and illustrated, but should be constructed to cover all modifications that may fall within the scope of the appended claims.

What is claimed is:

1. A lithographic method for reducing feature size comprising the steps of:
a. applying a first exposure step using a first mask to print standard circuit device line features;
b. applying a second exposure step using a second mask enabling a sub-threshold exposure dose to trim the circuit device line features in the exposed level,
wherein higher performance of devices is achieved as a result of said sub-threshold trim dose to device line features.

2. The lithographic method as claimed in claim 1, wherein said second mask enables trimming of the circuit device line features in the exposed level without substantial degradation of a resist profile.

3. The lithographic method as claimed in claim 1, wherein said second mask comprises non-transmissive regions for substantially blocking exposure to corresponding regions of a chip being fabricated during an photolithographic exposure dose, and at least one region having partial transmissivity for providing said sub-threshold exposure dose to corresponding circuit device line features.

4. The lithographic method as claimed in claim 1, wherein said circuit device line feature includes a gate channel length.

5. A mask for use in a lithographic process comprising non-transmissive regions for substantially blocking exposure to corresponding regions of a chip being fabricated during an photolithographic exposure dose, and one or more regions having partial transmissivity for tailoring an amount of energy applied to corresponding regions of a chip having a patterned photoresist layer for reducing feature dimensions of a device fabricated in said corresponding regions when subject to said photolithographic exposure dose, wherein multiple trim doses may be applied to different regions of an exposure field resulting in different image size adjustments within one lithographic field.

6. The mask as claimed in claim 5, wherein an amount of energy applied to corresponding regions of a chip is on the order of 1 mJ/cm².

7. The mask as claimed in claim 5, enabling reduction of feature dimensions of a device by less than 5 nm in said corresponding regions.

8. The mask as claimed in claim 5, wherein said mask is applied during a photolithographic exposure step in a sequence before or after printing standard features of said devices in said photoresist layer.

9. The mask as claimed in claim 5, wherein said non-transmissive regions includes a light blocker layer.

10. The mask as claimed in claim 9, wherein said light blocker layer comprises a layer of chrome.

11. The mask as claimed in claim 5, wherein each said one or more regions having partial transmissivity include regions have different degrees of partial transmissivity.

12. The mask as claimed in claim 11, wherein said one or more regions having partial transmissivity includes one or more light attenuating material layers.

13. The mask as claimed in claim 5, wherein said one or more regions having partial transmissivity includes a layer of MoSi.

14. The mask as claimed in claim 5, wherein said one or more regions having different degrees of partial transmissivity includes one light attenuating material layer having corresponding discrete thicknesses for tailoring amount of energy applied to tune performance of specific circuits in said corresponding regions.

15. The mask as claimed in claim 5, wherein said one or more regions having different degrees of partial transmissivity includes a light attenuating material layer stack having corresponding different layers etched through at said corresponding regions for tailoring amount of energy applied to tune performance of specific circuits in said corresponding regions.

16. A mask for use in a lithographic process for tuning performance of chips, said mask comprising multiple regions of multiple attenuator thicknesses, each region providing partial transmissivity for tailoring an amount of energy applied to different areas of chips having a patterned photoresist layer for reducing feature dimensions of devices fabricated in each said chip at said corresponding regions when subject to said photolithographic exposure dose, wherein different regions of a chip may be modulated to optimize power and performance of said chip by application of said single exposure dose.

17. The mask as claimed in claim 16, wherein said mask comprises a matrix of regions, each region having a light attenuating material layer providing a different partial transmissivity.

18. A method of manufacturing a photolithographic mask for use in a photolithographic process that enables performance tuning of chips, said method comprising the steps of:
a. providing a light-transmissive substrate;
b. forming atop said light-transmissive substrate a single attenuator layer of a thickness sufficient to appreciably absorb all light at an exposure wavelength,
c. applying a photoresist layer atop said single attenuator layer;
d. exposing and developing a region R[i], where i=1; and,
e. etching said single attenuator layer for a specific period of time t[i] to form a desired attenuator thickness x[i] in region R[i], wherein said photolithographic mask comprises non-transmissive regions for substantially blocking exposure to corresponding regions of a chip being fabricated during an photolithographic exposure dose, and one or more regions R[i] having partial transmissivity for tailoring an amount of energy applied to corresponding regions of a chip having a patterned photoresist layer for reducing feature dimensions of a device fabricated in said corresponding regions when subject to said photolithographic exposure dose.

19. The method as claimed in claim 18, further comprising the steps of: stripping said photoresist layer and repeating steps c) through e) to form regions R[i], where i=2, . . . , n.

20. The method as claimed in claim 18, further comprising the steps of: forming atop said single attenuator layer a blocker layer with effectively zero transmission at an exposure wavelength, said etching step e) including etching said blocker layer in said regions R[i], where i=2, . . . , n.

21. The method as claimed in claim 20, wherein said blocker layer comprises chrome.

22. The method as claimed in claim 18, wherein said step b) comprises forming a multi-film stack of different attenuator layers whose aggregate attenuation appreciably absorbs all light at the exposure wavelength atop said light-transmissive substrate, said method steps c)-e) including exposing and developing one or more regions R[i], where i=1, 2, . . . , n that require a top attenuator film to be removed, said method further comprising: etching the top attenuator layer of said multi-film attenuator stack at said one or more regions R[i].

23. The method as claimed in claim 22, further comprising the steps of: stripping said photoresist layer and exposing, developing and etching some or all regions R[i] that require a second attenuator film to be removed, said steps of stripping said photoresist layer and exposing, developing and etching some or all regions R[i] that require subsequent attenuator levels of said attenuation stack to be removed being repeated until desired attenuator profiles are achieved.

24. A method of manufacturing a photolithographic mask for use in a photolithographic process that enables performance tuning of chips, said method comprising the steps of:
a. providing a light-transmissive substrate;
b. forming atop said light-transmissive substrate a multi-film attenuator stack of different attenuator layers whose aggregate attenuation appreciably absorbs all light at the exposure wavelength;
c. applying a photoresist layer atop said multi-film attenuator stack;
d. exposing and developing one or more regions R[i], where i=1, 2, . . . , n that require a top attenuator film of said to be removed;
e. etching the top attenuator layer of said multi-film attenuator stack at said one or more regions R[i]; and,
f. repeating said steps c)-e) at one or more regions R[i] that require second and subsequent attenuator film layers to be removed from said multi-film attenuator stack to be removed until desired attenuator profiles are achieved.

25. The method as claimed in claim 24, further comprising the steps of: forming atop said multi-film attenuator stack a blocker layer with effectively zero transmission at an exposure wavelength, said etching step e) including etching said blocker layer in said regions R[i], where i=2, . . . , n.

26. The method as claimed in claim 25, wherein said blocker layer comprises chrome.

27. A method of manufacturing a photolithographic mask for use in a photolithographic process that enables performance tuning of chips, said method comprising the steps of:
a. forming atop a light-transmissive substrate a single attenuator film layer, said single attenuator film layer comprising a thinnest layer of film for one or more mask regions R[i], where i=1, 2, . . . , n;
b. providing a protective film over this region R[i] to prevent subsequent films from affecting it;
c. forming an incremental single attenuator film layer equivalent to the difference in thickness between the thinnest film and next thinnest film for one or more mask regions R[i];
d. providing a protective film over this region R[i] to prevent subsequent films from affecting it;
e. repeating steps c) and d) until all of the desired attenuator profiles are created, and
f. stripping the protective films utilized in creating the photomask.

28. The method of claim 27, wherein said step a) and step c) and e) of forming single and incremental single attenuator film layers comprises depositing material of a single composition.

29. The method as claimed in claim 27, wherein said single and incremental single attenuator film layers comprise a layer of MoSi.

30. The method as claimed in claim 27, wherein said single and incremental single attenuator film layers comprise material attenuator layers of different compositions.

31. A mask for use in a lithographic process for tuning performance of chips, said mask comprising multiple regions of multiple attenuator thicknesses, each region providing partial transmissivity for tailoring an amount of energy applied to corresponding regions of a chip having a patterned photoresist layer for reducing feature dimensions of a device fabricated in said corresponding regions when subject to said photolithographic exposure dose, wherein different regions of a chip may be modulated to optimize power and performance of said chip by application of said single exposure dose.

32. The mask as claimed in claim 31, wherein said mask comprises a m×n matrix of regions corresponding to m×n array of chips in a single lithographic field.

33. A method for tuning performance of chips having silicon containing gate channels, said method comprising:
a. providing an photolithographic exposure field comprised of multiple chips;
b. applying a dual trim exposure mask having corresponding multiple individual attenuator thicknesses, each region providing partial transmissivity for applying additional amounts of energy to corresponding chips having a patterned photoresist layer for reducing feature dimensions of devices fabricated in said corresponding chips when subject to a photolithographic exposure dose, wherein said dual trim exposure mask is used to modulate performance of devices across each individual field.

34. The method as claimed in claim 33, wherein said dual trim exposure mask comprises a m×n matrix of regions corresponding to m×n array of chips in a single lithographic field.
